(19) United States
(12) Patent Application Publication
(10) Pub. No.: US 2025/0004053 A1
(43) Pub. Date: Jan. 2, 2025

(54) ALTERNATOR MONITORING METHODS AND SYSTEMS

(71) Applicant: PETROLIAM NASIONAL BERHAD (PETRONAS), Kuala Lumpur (MY)

(72) Inventors: Salmey Bin ABDUL HALIM, Kuala Lumpur (MY); Abdul Razak Bin ABDUL RAHMAN, Kuala Lumpur (MY); Mohamed Nazim Bin HAMID, Kuala Lumpur (MY); Abdul Rahman Bin WARUAH MATOLLAH, Kuala Lumpur (MY); Abu Zharr Bin ABU HURAIRAH, Kuala Lumpur (MY)

(21) Appl. No.: 18/709,229

(22) PCT Filed: Nov. 8, 2022
(86) PCT No.: PCT/MY2022/050105

§ 371 Date: May 10, 2024

(30) Foreign Application Priority Data
Nov. 12, 2021 (MY) PI2021006766

(51) Int. Cl. G01R 31/34; G01R 31/40

(52) U.S. Cl. CPC G01R 31/34; G01R 31/40

(57) ABSTRACT

Methods and systems for monitoring an alternator are disclosed. A method of monitoring an alternator comprises: receiving alternator output data indicating an electrical output of an alternator; estimating an expected excitation current in a rotor of the alternator from the alternator output data; estimating an equivalent open circuit voltage of the alternator from the expected excitation current estimated; plotting a characteristic test curve for the alternator using the estimated equivalent open circuit voltage and the measured excitation current in the rotor of the alternator; and assessing a condition of the rotor of the alternator using the characteristic test curve.

### TECHNICAL FIELD

The present disclosure relates to methods and systems for monitoring alternators and in particular to methods and systems for assessing the condition of alternator rotor windings.

### BACKGROUND

Electrical generators generally comprise two main parts, a mechanical part such as an engine or a turbine which generates rotational motion and an electrical part known as an alternator which converts the rotational motion into electrical energy in the form of alternating current.

An alternator comprises a rotating magnet called a rotor which moves relative to a stationary set of windings in an iron core called a stator. The rotor typically comprises a set of windings around an iron which induce a magnetic field when a current is applied to the windings in the rotor.

It is estimated that approximately 35 percent of alternator failures are caused by faults developing in the rotor. Therefore, it is important to monitor the condition of rotors in alternators to identify faults which may cause a deterioration in performance. However, because the rotor is in motion during operation of an alternator it is not possible to install devices to monitor the condition of the rotor while it is operating. Therefore, it is necessary to take the alternator offline to perform a physical inspection of the condition of the rotor.

### SUMMARY

According to a first aspect of the present disclosure, a method of monitoring an alternator is provided. The method comprises: receiving alternator output data indicating an electrical output of an alternator; estimating an expected excitation current in a rotor of the alternator from the alternator output data; estimating an equivalent open circuit voltage of the alternator from the expected excitation current estimated; plotting a characteristic test curve for the alternator using the estimated equivalent open circuit voltage and the measured excitation current in the rotor of the alternator; and assessing a condition of the rotor of the alternator using the characteristic test curve.

By using the alternator output data to determine the expected excitation current in the rotor of the alternator, the performance of the alternator can be assessed while the alternator is online.

In an embodiment, the method further comprises looking up a first characteristic reference curve for the alternator and wherein estimating an excitation current in the rotor of the alternator from the alternator output data comprises using the first characteristic reference curve. The first characteristic reference curve for the alternator may be a V-curve

In an embodiment, the method further comprises looking up a second characteristic reference curve for the alternator and wherein estimating an equivalent open circuit voltage of the alternator from the expected excitation current in the rotor using the second characteristic curve.

The second characteristic curve for the alternator may be a No Load Saturation or Open Circuit Characteristic curve.

According to a second aspect of the present disclosure a method of monitoring an alternator is provided. The method comprises: receiving alternator output data indicating an electrical output of an alternator, the alternator output data comprising a measured excitation current in the rotor of the alternator; estimating an expected excitation current in a rotor of the alternator from the alternator output data; and assessing a condition of the rotor of the alternator by comparing the expected excitation current in the rotor of the alternator with the measured excitation current in the rotor of the alternator.

In an embodiment, comparing the expected excitation current in the rotor of the alternator with the measured excitation current in the rotor of the alternator comprises calculating a deviation between the expected excitation current and the measured excitation current.

In an embodiment, the method further comprises looking up a first characteristic reference curve for the alternator and wherein estimating an excitation current in the rotor of the alternator from the alternator output data comprises using the characteristic reference curve. The first characteristic reference curve may be a V-curve.

Embodiments of both the first aspect and the second aspect may further comprise generating a graph showing the condition of the rotor of the alternator. The graph may show the condition of the rotor of the alternator over a time period.

According to a third aspect of the present disclosure a computer readable medium storing processor executable instructions which when executed on a processor cause the processor to carry out a method as set out above is provided.

According to a fourth aspect of the present disclosure, an alternator monitoring system is provided. The alternator monitoring system comprises: a processor and a data storage device storing computer program instructions operable to cause the processor to: receive alternator output data indicating an electrical output of an alternator; estimate an expected excitation current in a rotor of the alternator from the alternator output data; estimate an equivalent open circuit voltage of the alternator from the expected excitation current estimated; plotting a characteristic test curve for the alternator using the estimated equivalent open circuit voltage and the measured excitation current in the rotor of the alternator; and assess a condition of the rotor of the alternator using the characteristic test curve.

In an embodiment, the data storage device further stores computer program instructions operable to cause the processor to: look up a first characteristic reference curve for the alternator; and estimate an excitation current in the rotor of the alternator from the alternator output data using the first characteristic reference curve. The first characteristic reference curve may be a V-curve.

In an embodiment, the data storage device further stores computer program instructions operable to cause the processor to: look up a second characteristic reference curve for the alternator and estimate an equivalent open circuit voltage of the alternator from the expected excitation current in the rotor using the second characteristic reference curve. The second characteristic reference curve may be a No Load Saturation or Open Circuit Characteristic curve.

According to a fifth aspect of the present disclosure, an alternator monitoring system is provided. The alternator monitoring system comprises: a processor and a data storage device storing computer program instructions operable to cause the processor to: receive alternator output data indicating an electrical output of an alternator, the alternator output data comprising a measured excitation current in the rotor of the alternator; estimate an expected excitation current in a rotor of the alternator from the alternator output data; and assess a condition of the rotor of the alternator by comparing the expected excitation current in the rotor of the alternator with the measured excitation current in the rotor of the alternator.

In an embodiment, the data storage device further stores computer program instructions operable to cause the processor to: compare the expected excitation current in the rotor of the alternator with the measured excitation current in the rotor of the alternator by calculating a deviation between the expected excitation current and the measured excitation current.

In an embodiment, the data storage device further stores computer program instructions operable to cause the processor to: look up a first characteristic reference curve for the alternator; and estimate an excitation current in the rotor of the alternator from the alternator output data using the characteristic reference curve. The first characteristic reference curve may be a V-curve

In embodiments of both the fourth and fifth aspects the data storage device further stores computer program instructions operable to cause the processor to: generate a graph showing the condition of the rotor of the alternator. The graph may show the condition of the rotor of the alternator over a time period.

Further embodiments of the present invention are set out in the following clauses:
1. A method of monitoring an alternator, the method comprising:
   receiving alternator output data indicating an electrical output of an alternator;
   estimating an expected excitation current in a rotor of the alternator from the alternator output data;
   estimating an equivalent open circuit voltage of the alternator from the expected excitation current estimated;
   plotting a characteristic test curve for the alternator using the estimated equivalent open circuit voltage and the measured excitation current in the rotor of the alternator; and
   assessing a condition of the rotor of the alternator using the characteristic test curve.
2. A method according to clause 1, further comprising looking up a first characteristic reference curve for the alternator and wherein estimating an excitation current in the rotor of the alternator from the alternator output data comprises using the first characteristic reference curve.
3. A method according to clause 2, wherein the first characteristic reference curve for the alternator is a V-curve.
4. A method according to any preceding clause, further comprising looking up a second characteristic reference curve and wherein estimating an equivalent open circuit voltage using the estimated excitation current in the rotor comprises using the second characteristic reference curve.
5. A method according to clause 4, wherein the second characteristic reference curve is a no load saturation or open circuit characteristic curve.
6. A method according to any preceding clause, wherein the characteristic test curve is a no load saturation or open circuit characteristic test curve.
7. A method of monitoring an alternator, the method comprising:
   receiving alternator output data indicating an electrical output of an alternator, the alternator output data comprising a measured excitation current in the rotor of the alternator;
   estimating an expected excitation current in a rotor of the alternator from the alternator output data; and
   assessing a condition of the rotor of the alternator by comparing the expected excitation current in the rotor of the alternator with the measured excitation current in the rotor of the alternator.
8. A method according to clause 7, wherein comparing the expected excitation current in the rotor of the alternator with the measured excitation current in the rotor of the alternator comprises calculating a deviation between the expected excitation current and the measured excitation current.
9. A method according to clause 7 or clause 8, further comprising looking up a first characteristic reference curve for the alternator and wherein estimating an excitation current in the rotor of the alternator from the alternator output data comprises using the characteristic reference curve.
10. A method according to clause 9, wherein the first characteristic reference curve for the alternator is a V-curve.
11. A method according to any preceding clause, further comprising generating a graph showing the condition of the rotor of the alternator.
12. A method according to clause 11, wherein the graph showing the condition of the rotor of the alternator shows results over a time period.
13. A computer readable medium storing processor executable instructions which when executed on a processor cause the processor to carry out a method according to any one of clauses 1 to 12.
14. An alternator monitoring system comprising: a processor and a data storage device storing computer program instructions operable to cause the processor to:
   receive alternator output data indicating an electrical output of an alternator;
   estimate an expected excitation current in a rotor of the alternator from the alternator output data;
   estimate an equivalent open circuit voltage of the alternator from the expected excitation current estimated;
   plotting a characteristic test curve for the alternator using the estimated equivalent open circuit voltage and the measured excitation current in the rotor of the alternator; and
   assess a condition of the rotor of the alternator using the characteristic test curve.
15. An alternator monitoring system according to clause 14, wherein the data storage device further stores computer program instructions operable to cause the processor to: look up a first characteristic reference curve for the alternator; and estimate an excitation current in the rotor of the alternator from the alternator output data using the first characteristic reference curve.
16. An alternator monitoring system according to clause 15, wherein the first characteristic reference curve for the alternator is a V-curve.
17. An alternator monitoring system according to any one of clauses 14 to 16, wherein the data storage device further stores computer program instructions operable to cause the processor to: look up a second characteristic reference curve; and estimate an equivalent open circuit voltage using the estimated excitation current in the rotor comprises using the second characteristic reference curve.
18. An alternator monitoring system according to clause 17, wherein the second characteristic reference curve is a no load saturation or open circuit characteristic curve.
19. An alternator monitoring system according to any one of clauses 14 to 18, wherein the characteristic test curve is a no load saturation or open circuit characteristic test curve.
20. An alternator monitoring system comprising: a processor and a data storage device storing computer program instructions operable to cause the processor to:
   receive alternator output data indicating an electrical output of an alternator, the alternator output data comprising a measured excitation current in the rotor of the alternator;
   estimate an expected excitation current in a rotor of the alternator from the alternator output data; and
   assess a condition of the rotor of the alternator by comparing the expected excitation current in the rotor of the alternator with the measured excitation current in the rotor of the alternator.
21. An alternator monitoring system according to clause 20, wherein the data storage device further stores computer program instructions operable to cause the processor to: compare the expected excitation current in the rotor of the alternator with the measured excitation current in the rotor of the alternator by calculating a deviation between the expected excitation current and the measured excitation current.
22. An alternator monitoring system according to clause 20 or 21, wherein the data storage device further stores computer program instructions operable to cause the processor to: look up a first characteristic reference curve for the alternator; and estimate an excitation current in the rotor of the alternator from the alternator output data using the characteristic reference curve.
23. An alternator monitoring system according to clause 22, wherein the first characteristic reference curve for the alternator is a V-curve.
24. An alternator monitoring system according to any one of clauses 14 to 23, wherein the data storage device further stores computer program instructions operable to cause the processor to: generate a graph showing the condition of the rotor of the alternator.
25. An alternator monitoring system according to clause 24, wherein the graph showing the condition of the rotor of the alternator shows results over a time period.

### BRIEF DESCRIPTION OF THE DRAWINGS

In the following, embodiments of the present invention will be described as non-limiting examples with reference to the accompanying drawings in which:

FIG. 1 is a block diagram showing an alternator monitoring system according to an embodiment of the present invention coupled to a generator comprising an alternator;

FIG. 2 is a block diagram showing an alternator monitoring system according to an embodiment of the present invention;

FIG. 3A is a flowchart showing a method of monitoring an alternator according to an embodiment of the present invention;

FIG. 3B is a flowchart showing a method of monitoring an alternator according to an embodiment of the present invention;

FIG. 4 is a V-curve illustrating the estimation of expected DC excitation current in a method according to an embodiment of the present invention;

FIG. 5 is an open circuit characteristic curve illustrating the estimation of the equivalent open circuit characteristic voltage in a method according to an embodiment of the present invention;

FIG. 6A is an open circuit characteristic curve for an alternator showing current operating parameters calculated according to an embodiment of the present invention;

FIG. 6B is an open circuit characteristic curve for an alternator showing operating parameters overtime calculated according to an embodiment of the present invention; and

FIG. 7 is a V-curve for an alternator showing calculated and measured operating parameters according to an embodiment of the present invention.

### DETAILED DESCRIPTION

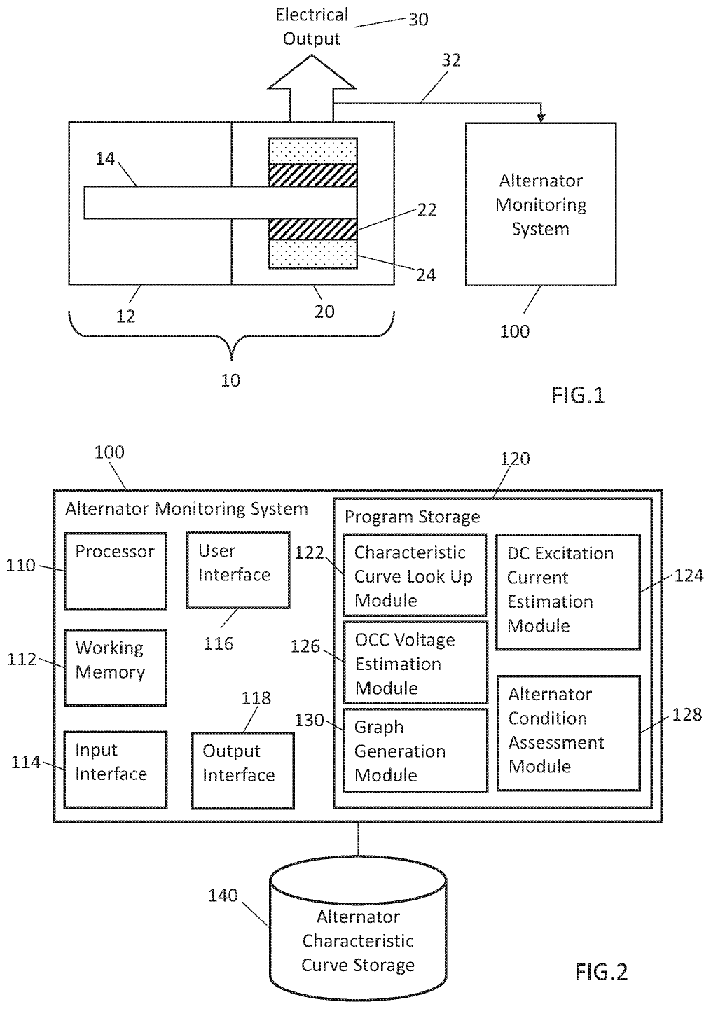

FIG. 1 is a block diagram showing an alternator monitoring system according to an embodiment of the present invention coupled to a generator comprising an alternator. As shown in FIG. 1, the generator 10 comprises a mechanical part 12 such as an engine or a turbine. The mechanical part 12 drives a shaft 14 which couples the mechanical part 12 to an alternator 20. The alternator 20 comprises a rotor 22 which is coupled to the shaft 14 and a stator 24. When the shaft 14 rotates, the rotor 22 rotates relative to the stator 24. The stator 24 comprises an iron core and a set of coil windings. The rotor 22 comprises a set of coil windings around an iron core. An armature current is applied to the coil windings in the rotor 22 which produces a magnetic field and the rotation of the rotor 22 generates an electromotive force in the coils of the stator 24 which generates an alternating current.

The alternating current forms an electrical output 30 of the generator. The alternator monitoring system 100 receives output data 32 which comprises indications of the electrical output 30 such as real power, current output and power factor of the alternator 20. The alternator monitoring system 100 uses the output data 32 to determine an expected excitation current based on the output data 32 and using this expected excitation current, the alternator monitoring system 100 allows an online assessment of the condition of the rotor 22 without the need for any additional sensors or devices to be applied to the rotor 22 or any requirement the generator 10 to be taken offline for a physical inspection.

FIG. 2 shows an alternator monitoring system according to an embodiment of the present invention. The alternator monitoring system 100 is a computer system with memory that stores computer program modules which implement geographic data processing methods according to embodiments of the present invention.

The alternator monitoring system 100 comprises a processor 110, a working memory 112, an input interface 114, a user interface 116, an output interface 118, program storage 120 and data storage 140. The processor 110 may be implemented as one or more central processing unit (CPU) chips. The program storage 120 is a non-volatile storage device such as a hard disk drive which stores computer program modules. The computer program modules are loaded into the working memory 112 for execution by the processor 110. The input interface 114 is an interface which allows data, such as output data from an alternator to be received by the alternator monitoring system 100. The input interface 114 may be a wireless network interface such as a Wi-Fi or Bluetooth interface, alternatively it may be a wired interface. The user interface 116 allows a user of the alternator monitoring system 100 to input data such as output data from an alternator and may be implemented as a graphical user interface. The output interface 118 outputs data and may be implemented as a display or a data interface.

The program storage 120 stores a characteristic curve look up module 122, a DC excitation current estimation module 124, an open circuit characteristic (OCC) voltage look up module 126, an alternator condition assessment module 128 and a graph generation module 130. The computer program modules cause the processor 110 to execute various data processing which is described in more detail below. The program storage 120 may be referred to in some contexts as computer readable storage media and/or non-transitory computer readable media. As depicted in FIG. 2, the computer program modules are distinct modules which perform respective functions implemented by the alternator monitoring system 100. It will be appreciated that the boundaries between these modules are exemplary only, and that alternative embodiments may merge modules or impose an alternative decomposition of functionality of modules. For example, the modules discussed herein may be decomposed into sub-modules to be executed as multiple computer processes, and, optionally, on multiple computers. Moreover, alternative embodiments may combine multiple instances of a particular module or sub-module. It will also be appreciated that, while a software implementation of the computer program modules is described herein, these may alternatively be implemented as one or more hardware modules (such as field-programmable gate array(s) or application-specific integrated circuit(s)) comprising circuitry which implements equivalent functionality to that implemented in software.

Although the alternator monitoring system 100 is described with reference to a computer, it should be appreciated that the alternator monitoring system 100 may be formed by two or more computers in communication with each other that collaborate to perform a task. For example, but not by way of limitation, an application may be partitioned in such a way as to permit concurrent and/or parallel processing of the instructions of the application. Alternatively, the data processed by the application may be partitioned in such a way as to permit concurrent and/or parallel processing of different portions of a data set by the two or more computers. In an embodiment, virtualization software may be employed by the alternator monitoring system 100 to provide the functionality of a number of servers that is not directly bound to the number of computers in the alternator monitoring system 100. In an embodiment, the functionality disclosed above may be provided by executing the application and/or applications in a cloud computing environment. Cloud computing may comprise providing computing services via a network connection using dynamically scalable computing resources. A cloud computing environment may be established by an enterprise and/or may be hired on an as-needed basis from a third party provider.

The alternator monitoring system 100 is coupled to an alternator characteristic curve storage 140. The alternator characteristic curve storage is a database which stores characteristic curves such as V curves and no load saturation or open circuit characteristic curves which show the relationship between armature current and field current for alternators and open circuit characteristic voltage curves for alternators. The characteristic curves stored in the alternator characteristic curve storage 140 may indicate the characteristics of individual alternators when manufactured or tested following assembly.

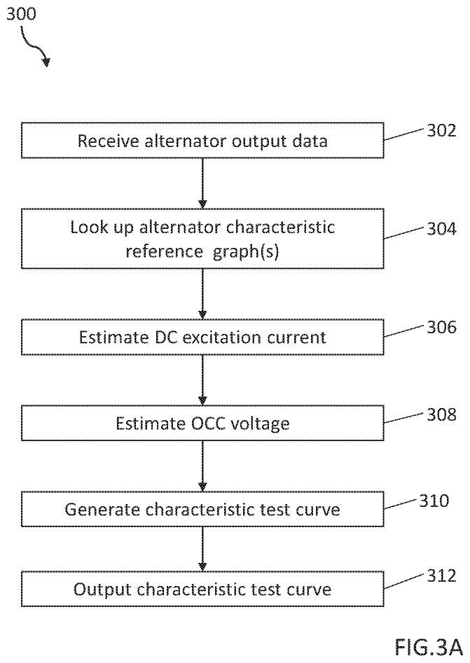

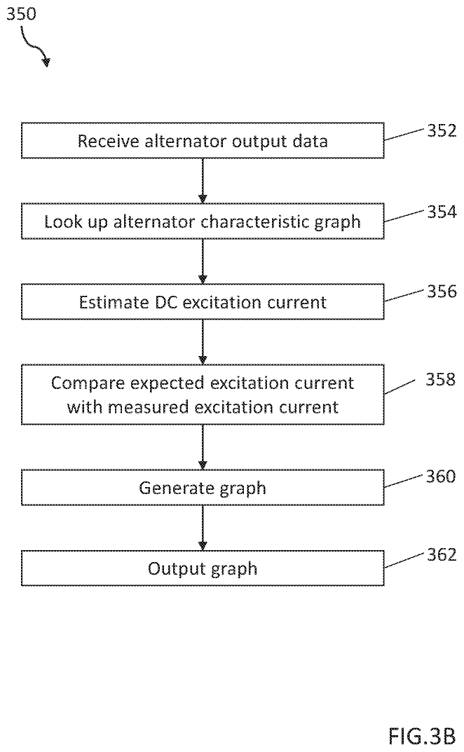

FIG. 3A and FIG. 3B are flowcharts showing methods of monitoring an alternator according to an embodiment of the present invention. The method 300 shown in FIG. 3A and the method 350 shown in FIG. 3B are carried out by the alternator monitoring system 100 shown in FIG. 2.

FIG. 3A shows a method of monitoring an alternator in which a characteristic test curve for the alternator is generated.

In step 302, the alternator monitoring system 100 receives alternator output data. The alternator output data comprises indications of the instantaneous output of the alternator 20, for example the real power, output current and/or power factor of the alternator 20. The alternator output data also comprises indications of the actual output voltage and a measured excitation current of the alternator. The alternator output data may be received through the input interface 114 of the alternator monitoring system 100, for example via a network connection linked to a control module of the alternator 20. Alternatively, the alternator output data may be input by a user into the user interface 116 of the alternator monitoring system 100. The user may read the alternator output data from a display of the control module on the alternator 20 and input the data into the user interface 116. In some embodiments, the user may input the alternator output data into a mobile device for transmission to the alternator monitoring system 100 via a network connection. The alternator output data may be provided to the alternator monitoring system 100 with an indication of the alternator to which it relates, for example a tag number or serial number of the alternator. Additionally, the alternator output data may be provided to the alternator monitoring system 100 with a time stamp indicating the time and data at which the output data was captured.

In step 304, the characteristic curve look up module 122 is executed by the processor 110 of the alternator monitoring system 100 to look up characteristic curves for the alternator in the alternator characteristic curve storage 140. The characteristic curves may be looked up using the indication of the alternator. The characteristic curves stored in the alternator characteristic curve storage 140 comprise V curves and open circuit characteristic (OCC) voltage curves. The characteristic curves may be specific to the particular alternators and as mentioned above may indicate the characteristics of the alternators when manufactured or initially tested.

In step 306, the DC excitation current excitation module 124 is executed by the processor 110 of the alternator monitoring system 100 to estimate the excitation current in the alternator based on the alternator output data.

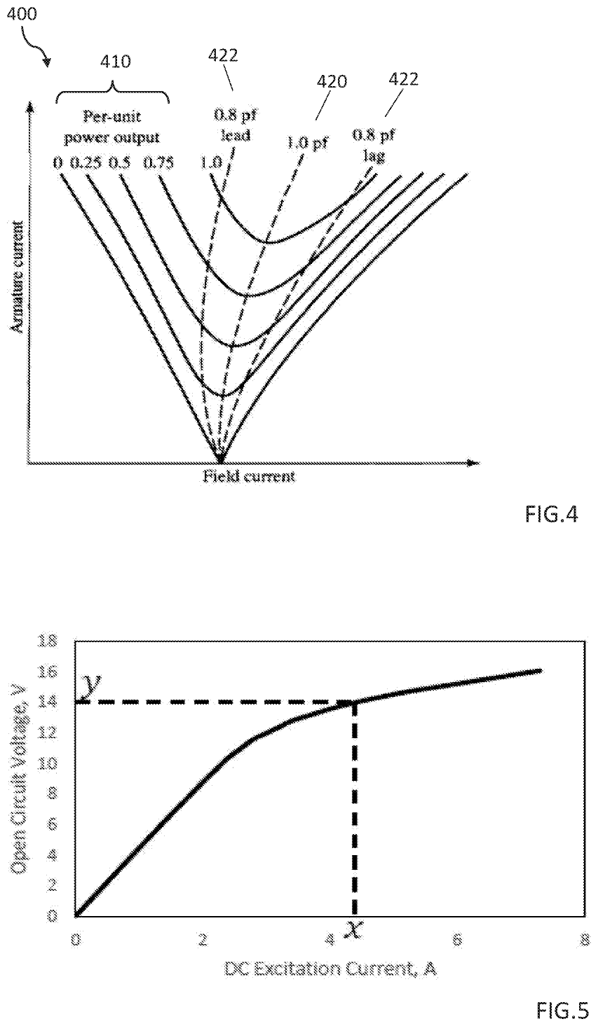

FIG. 4 is a V-curve illustrating the estimation of expected DC excitation current in a method according to an embodiment of the present invention. As shown in FIG. 4, the V-curve 400 shows the relationship between armature current and field current for different power outputs 410. The armature current is the current in the stator and the field current is the current in the rotor. FIG. 4 shows power outputs of 0, 0.25, 0.5, 0.75 and 1. FIG. 4 also shows different power factor lags or leads. The curves for 0.8 power factor lead 422, unity power factor compounding curve 420 and 0.8 power factor lag 424 are shown in FIG. 4.

The field current can be estimated by extrapolation from the V curve shown in FIG. 4. Since the alternator output data includes indications of the power output, the power factor and/or the output current of the alternator, the alternator output data can be used in combination with the V curve to estimate the field current which corresponds to the expected DC excitation current. The output current of the alternator corresponds to the armature current and using this in combination with the power factor and power output, the field current or expected excitation current can be estimated.

Returning now to FIG. 3A, in step 308, the OCC voltage estimation module 126 is executed by the processor 110 of the alternator monitoring system 100 to estimate the equivalent open circuit characteristic (OCC) voltage using the expected DC excitation current determined in step 306.

FIG. 5 is an open circuit characteristic curve illustrating the estimation of the equivalent open circuit characteristic voltage in a method according to an embodiment of the present invention. As shown in FIG. 5, the open circuit characteristic curve shows the relationship between DC excitation current and open circuit voltage for the alternator.

Using the expected excitation current determined in step 306, the equivalent open circuit characteristic voltage can be estimated from the open circuit characteristic curve. As shown in FIG. 5, if the DC excitation current has a value x, the equivalent open circuit voltage can be estimated as y.

Returning again to FIG. 3A, in step 310, the graph generation module 130 is executed by the processor 110 to assess the condition of the alternator by generating a characteristic test curve. Step 310 may comprise of plotting the equivalent no load saturation or open circuit characteristic test of the alternator using the measured excitation current obtained from the alternator output data comprises indications of the instantaneous output of the alternator 20 and the equivalent open circuit voltage of the alternator estimated in step 308 against the no load saturation or open circuit characteristic curve of the alternator stored in the alternator characteristic curve storage 140.

The graphical deviation between the equivalent no load saturation or open circuit characteristic plot and the no load saturation or open circuit characteristic curve of the alternator may be seen. For example, on a healthy alternator, it is expected that the equivalent no load saturation or open circuit characteristic plot should be on the no load saturation or open circuit characteristic curve of the alternator. However, a machine can be considered as underperforming or experiencing degradation if the equivalent no load saturation or open circuit characteristic plot is located under the no load saturation or open circuit characteristic curve. If the equivalent no load saturation or open circuit characteristic plot is located too far under the no load saturation or open circuit characteristic curve, the machine can be considered as experiencing failure and further operation of the machine will result in further damage.

In step 310, the graph generation module 130 is executed by the processor 110 of the alternator monitoring system 100 to generate a graph showing the assessment results. The graph may comprise a graph showing the equivalent no load saturation or open circuit characteristic plot estimated over time or the calculated expected DC excitation current and the measured DC excitation current over time.

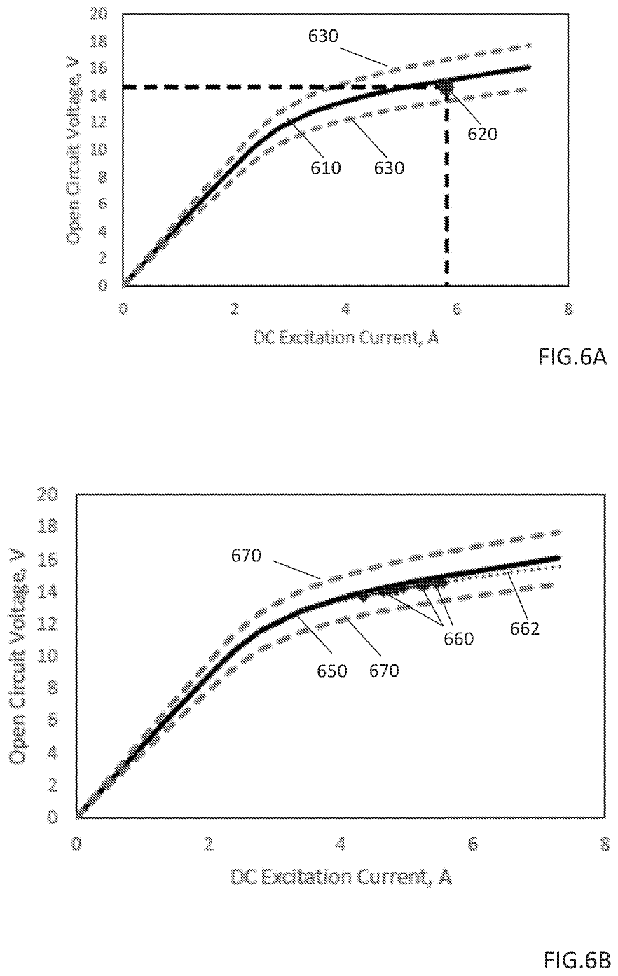

Alternatively, the graph may show the calculated operating parameters plotted on a characteristic curve of the alternator. Examples of such graphs are shown in FIGS. 6A and 6B.

FIG. 6A is a no load saturation or open circuit characteristic curve for an alternator showing current operating parameters calculated according to an embodiment of the present invention and FIG. 6B is a V-curve for an alternator showing current operating parameters calculated according to an embodiment of the present invention.

As shown in FIG. 6A, the calculated equivalent open circuit voltage is plotted against the measured DC excitation current. The plot shows the characteristic curve 610 stored in the alternator characteristic curve storage 140. A point 620 corresponding to the calculated equivalent open circuit voltage and the measured DC excitation current is shown relative to the characteristic curve 610. In addition, dashed lines 630 representing a percentage deviation from the characteristic curve 610 are also shown on the plot. The dashed lines 630 may represent a deviation of 5% or 10% from the characteristic curve 610.

FIG. 6B is an open circuit characteristic for an alternator showing operating parameters over time calculated according to an embodiment of the present invention. As with FIG. 6A, the plot shows the characteristic curve 650 stored in the alternator characteristic curve storage 140. Multiple points 660 corresponding to the calculated equivalent open circuit voltages and the measured DC excitation current are shown relative to the characteristic curve 650. A trend line 662 is determined from the multiple points 660. As with FIG. 6A, the plot also includes dashed lines showing a percentage deviation from the characteristic curve 670.

Returning now to FIG. 3A, in step 312, the graph generated in step 312 is output by the output interface 118 of the alternator monitoring system 100. This step may comprise displaying the graph on a display to the user or sending the graph to a user device for display to the user.

The graphs generated in step 310 may be generated using multiple measurements. In some embodiments, such graphs may be plotted against a time axis, for example showing the variation of excitation current and measured DC excitation current, and/or the deviation over time.

FIG. 3B shows a method of monitoring an alternator in which an expected excitation current is compared with a measured excitation current.

Steps 352, 354 and 356 shown in FIG. 3B correspond to steps 302, 304 and 306 shown in FIG. 3A and the processing carried out in these steps is as described above with reference to FIG. 3A.

In step 358, the alternator condition assessment module 128 is executed by the processor 110 of the alternator monitoring system 100 to compare the expected excitation current calculated in step 356 with a measured excitation current received in step 352 as part of the alternator output data. The deviation between calculated expected DC excitation current and the measured DC excitation current may be calculated. This deviation may be determined as a percentage. The deviation may be compared with a threshold, and further actions may be recommended based on the percentage deviation. For example, a deviation of less than 5% may be considered as a minor deviation with no further action recommended, deviation of between 5% and 10% may be considered a significant deviation and further inspection may be recommended, for example a physical inspection may be scheduled. A deviation of greater than 10% may be considered a potential failure of the alternator and the alternator may be shut down.

In step 360, the graph generation module 130 is executed by the processor 110 of the alternator monitoring system 100 to generate a graph showing the deviation.

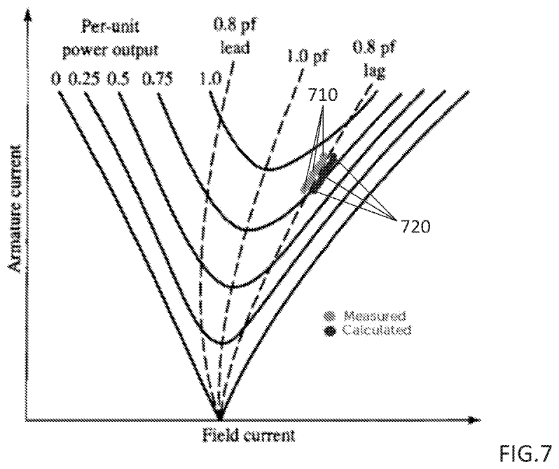

FIG. 7 is a V-curve for an alternator showing calculated and measured excitation current values. The measured values 710 correspond to values from the alternator output data and the calculated values 720 are the values calculated in step 356.

Returning now to FIG. 3B, in step 362, the graph generated in step 360 is output by the output interface 118 of the alternator monitoring system 100. This step may comprise displaying the graph on a display to the user or sending the graph to a user device for display to the user.

Whilst the foregoing description has described exemplary embodiments, it will be understood by those skilled in the art that many variations of the embodiments can be made within the scope and spirit of the present invention.

1. A method of monitoring an alternator, the method comprising:
receiving alternator output data indicating an electrical output of an alternator;
estimating an expected excitation current in a rotor of the alternator from the alternator output data;
estimating an equivalent open circuit voltage of the alternator from the estimated expected excitation current;
plotting a characteristic test curve for the alternator using the estimated equivalent open circuit voltage and a measured excitation current in the rotor of the alternator; and
assessing a condition of the rotor of the alternator using the characteristic test curve.

2. A method according to claim 1, further comprising looking up a first characteristic reference curve for the alternator and wherein estimating an excitation current in the rotor of the alternator from the alternator output data comprises using the first characteristic reference curve.

3. A method according to claim 2, wherein the first characteristic reference curve for the alternator is a V-curve.

4. A method according to claim 1, further comprising looking up a second characteristic reference curve and wherein estimating an equivalent open circuit voltage using the estimated excitation current in the rotor comprises using the second characteristic reference curve.

5. A method according to claim 4, wherein the second characteristic reference curve is a no load saturation or open circuit characteristic curve.

6. A method according to claim 1, wherein the characteristic test curve is a no load saturation or open circuit characteristic test curve.

7. A method of monitoring an alternator, the method comprising:
receiving alternator output data indicating an electrical output of an alternator, the alternator output data comprising a measured excitation current in a rotor of the alternator;
estimating an expected excitation current in a rotor of the alternator from the alternator output data; and
assessing a condition of the rotor of the alternator by comparing the expected excitation current in the rotor of the alternator with the measured excitation current in the rotor of the alternator.

8. A method according to claim 7, wherein comparing the expected excitation current in the rotor of the alternator with the measured excitation current in the rotor of the alternator comprises calculating a deviation between the expected excitation current and the measured excitation current.

9. A method according to claim 7, further comprising looking up a first characteristic reference curve for the alternator and wherein estimating an excitation current in the rotor of the alternator from the alternator output data comprises using the characteristic reference curve.

10. A method according to claim 9, wherein the first characteristic reference curve for the alternator is a V-curve.

11. A method according to claim 1, further comprising generating a graph showing the condition of the rotor of the alternator.

12. A method according to claim 11, wherein the graph showing the condition of the rotor of the alternator shows results over a time period.

13. A computer readable medium storing processor executable instructions which when executed on a processor cause the processor to carry out a method according to claim 1.

14. An alternator monitoring system comprising: a processor and a data storage device storing computer program instructions operable to cause the processor to:
receive alternator output data indicating an electrical output of an alternator;
estimate an expected excitation current in a rotor of the alternator from the alternator output data;
estimate an equivalent open circuit voltage of the alternator from the estimated expected excitation current;
plotting a characteristic test curve for the alternator using the estimated equivalent open circuit voltage and a measured excitation current in the rotor of the alternator; and
assess a condition of the rotor of the alternator using the characteristic test curve.

15. An alternator monitoring system according to claim 14, wherein the data storage device further stores computer program instructions operable to cause the processor to: look up a first characteristic reference curve for the alternator; and estimate an excitation current in the rotor of the alternator from the alternator output data using the first characteristic reference curve.

16. (canceled)

17. An alternator monitoring system according to claim 14, wherein the data storage device further stores computer program instructions operable to cause the processor to: look up a second characteristic reference curve; and estimate an equivalent open circuit voltage using the estimated excitation current in the rotor comprises using the second characteristic reference curve.

18-19. (canceled)

20. An alternator monitoring system comprising: a processor and a data storage device storing computer program instructions operable to cause the processor to:
receive alternator output data indicating an electrical output of an alternator, the alternator output data comprising a measured excitation current in a rotor of the alternator;
estimate an expected excitation current in a rotor of the alternator from the alternator output data; and
assess a condition of the rotor of the alternator by comparing the expected excitation current in the rotor of the alternator with the measured excitation current in the rotor of the alternator.

21. An alternator monitoring system according to claim 20, wherein the data storage device further stores computer program instructions operable to cause the processor to: compare the expected excitation current in the rotor of the alternator with the measured excitation current in the rotor of the alternator by calculating a deviation between the expected excitation current and the measured excitation current.

22. An alternator monitoring system according to claim 20, wherein the data storage device further stores computer program instructions operable to cause the processor to: look up a first characteristic reference curve for the alternator; and estimate an excitation current in the rotor of the alternator from the alternator output data using the characteristic reference curve.

23. (canceled)

24. An alternator monitoring system according to claim 20, wherein the data storage device further stores computer program instructions operable to cause the processor to: generate a graph showing the condition of the rotor of the alternator, wherein the graph showing the condition of the rotor of the alternator shows results over a time period.

25. (canceled)
